(19) United States
(12) Patent Application Publication
(10) Pub. No.: US 2013/0175914 A1
(43) Pub. Date: Jul. 11, 2013

(54) TWIN-SHAFT HINGE AND ELECTRONIC DEVICE WITH THE TWIN-SHAFT HINGE

(71) Applicant: Le-Yao LIN, New Taipei City (TW)

(72) Inventor: Le-Yao LIN, New Taipei City (TW)

(21) Appl. No.: 13/347,533

(22) Filed: Jan. 10, 2012

(51) Int. Cl. E05D 3/06; H05K 5/02

(52) U.S. Cl. 312/327; 16/366

(57) ABSTRACT

A twin-shaft hinge comprises a twin-shaft body, a first shaft, a first brake lining, a second shaft and a second brake lining: the twin-shaft body has mounting holes opened at its both flanks, each of which has retainers outside its opening's both sides, and a hold-down groove in one mounting hole and between two retainers; the first shaft has a pivot part, a holder linking the pivot part, and a stopper between the pivot part and the holder; the second shaft has a pivot part and a holder only; the first brake lining or the second brake lining is coupled with a pivot part and inserted into a mounting hole for one stopper. With the twin-shaft body, the first shaft, and the second shaft mutually coordinating, a first device body on one electronic device is turned to a second device body's rear side.

### BACKGROUND OF THE INVENTION

a) Field of the Invention

The present invention relates to a twin-shaft hinge and an electronic device with the twin-shaft hinge, especially a twin-shaft hinge which allows a turning angle to be freely adjusted and increased to a larger one and is installed in supports of an electronic device to be turned.

b) Description of the Prior Art

The evolution of computer developed to be a portable device has unexceptionally prompted all manufacturers to produce portable computers being available at all times and based on some indispensable factors such as durable electricity and computational efficiency which depend on power-saving elements and high-capacity batteries developed by semiconductor and battery manufacturers, respectively.

On the other hand, the mechanism for one computer without limitation of any occasion relies on a system manufacturer's design, for instance, an existing foldable notebook computer has twin pieces, one computer screen and one keyboard installed on two single pieces and constituting a foldable structure with an included angle of 90 degrees approximately, and is placed on one desk for convenient use but unfavorable to handheld operation.

The resolution herein is based on a tablet PC (Personal Computer) on which there is one display designed for a user's one hand holding the computer and other unoccupied hand manipulating a touch pen to click on functional keys or to write something on the touch panel.

In view of one computer for critical accesses completed by entering texts, a touch pen as one major means of a tablet PC operated on one palm for texts entered is a slow and hard-to-use tool compared with a keyboard and restricts or deteriorates convenience during texts entered into a computer despite its significant improvement in portability and convenience. Accordingly, the perspective of tablet PCs is not optimistic according to lots of persons' opinions and theses machines have been applicable to some specific purposes only, for instance, options checked by a physician visiting wards or a warehouseman making an inventory, except for texts entered.

To solve the problem of texts difficultly entered onto a tablet PC, some models are provided with a fanwise keypad designed on a touch panel and clicked on by two thumbs of one user holding a computer by hands. However, the speed to operate the computer by thumbs is much slower than that of operating another computer by a physical keyboard owing to the restricted extent of moving thumbs of two hands used to hold the computer as well as intrinsic insensitivity of thumbs.

Another design is a physical slip keypad which is ordinarily concealed inside and slipped outward for lots of texts to be entered. Like a keypad on a touch panel, this mechanism, however, needs fingers to hold a computer except insensitive thumbs which are used to operate the keypad and exhausts a holder whose hands operate the keypad and strenuously sustain a computer with its center of gravity out of hands due to a display extended backward.

Accordingly, the issue to change the structural design of one electronic device such as notebook computer and transfer a notebook computer as one tablet PC for use has become an urgent topic.

### SUMMARY OF THE INVENTION

The object of the present invention is to provide a twin-shaft hinge for any turning angle freely adjusted and increased to a larger one.

The other object of the present invention is to provide an electronic device with a twin-shaft hinge for any turning angle freely adjusted and increased to a larger one.

To deliver the said two objects, the present invention embodied by the following measures comprises a twin-shaft body, a first shaft, a first brake lining, a second shaft and a second brake lining for the first shaft's and the second shaft's respective ends connected to an electronic device.

The twin-shaft body has mounting holes opened at its both sides, retainers designed outside one mounting hole, and a hold-down groove which is located in one mounting hole and between retainers for one brake lining securely inserted; the first shaft comprises a pivot part, a holder connected to the pivot part, and a stopper between the pivot part and the holder; the second shaft comprises a pivot part and a holder; the first brake lining or the second brake lining is coupled with one corresponding pivot part and inserted into a mounting hole for the stopper on the first shaft corresponding to retainers which coordinates the stopper to restrict a turning angle of the first shaft.

The first shaft is intended for turning a first device body on an electronic device wherein the first device body is turned to an ultimate angle and further to a second device body's rear side according to the second shaft driven by the twin-shaft body.

To deliver the said purposes, the present invention can consist of the twin-shaft body, the first shaft and the second shaft only. Different from the previously mentioned structure, this structure without brake linings allows its shafts to be inserted into the twin-shaft body's mounting holes via pivot parts and delivers turning by means of friction between the pivot parts and the mounting holes.

Furthermore, a pivot part and a holder in the present invention combine one shaft to become a one-piece structure or are separately mounted on the shaft via an assembly process.

To deliver the other object hereinbefore, the present invention of an electronic device comprises a first device body, a second device body, supports in the device bodies and the twin-shaft hinge: the first device body or the second device body turns around the twin-shaft hinge which is fixed in the supports; the first device body of the electronic device is based on coordination of the first shaft and the second shaft to be turned to the second device body's rear side.

To enable a further understanding of the said objectives and the technological methods of the invention herein, the brief description of the drawings below is followed by the detailed description of the preferred embodiments.

### BRIEF DESCRIPTIONS OF THE DRAWINGS

FIG. 1 is the exploded perspective view for the present invention of a twin-shaft hinge.

FIG. 2 is the perspective view for the present invention of a twin-shaft hinge partially assembled.

FIG. 3 is the perspective view for the present invention of a twin-shaft hinge completely assembled.

FIG. 4 illustrates an additional embodiment for the present invention of a twin-shaft hinge.

FIG. 5 illustrates a further embodiment for the present invention of a twin-shaft hinge.

FIG. 6 is the exploded perspective view for the present invention of a twin-shaft hinge used in an electronic device.

FIG. 6A is the perspective view of the present invention (FIG. 6) partially magnified.

FIG. 7 illustrates the present invention of an electronic device with its screen opened to the first angle.

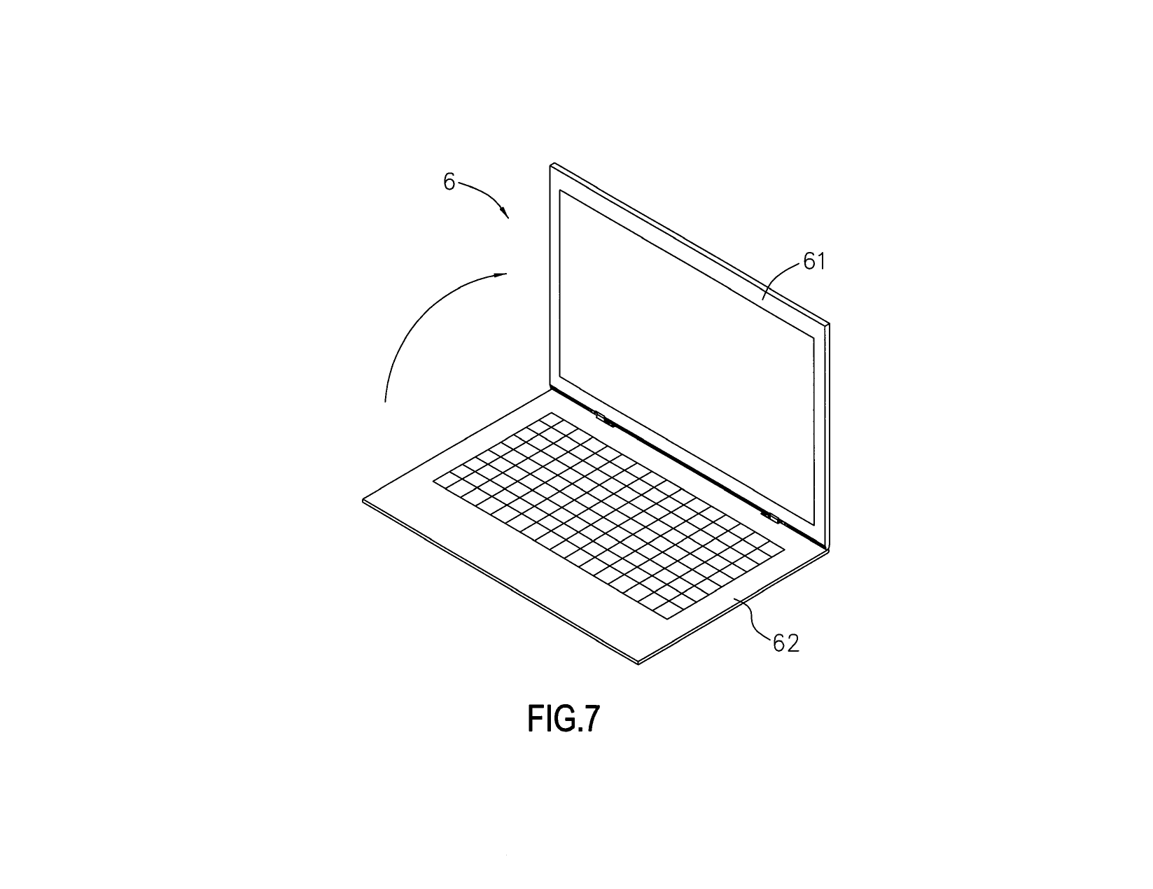

FIG. 8 illustrates the present invention of an electronic device with its screen opened to the second angle.

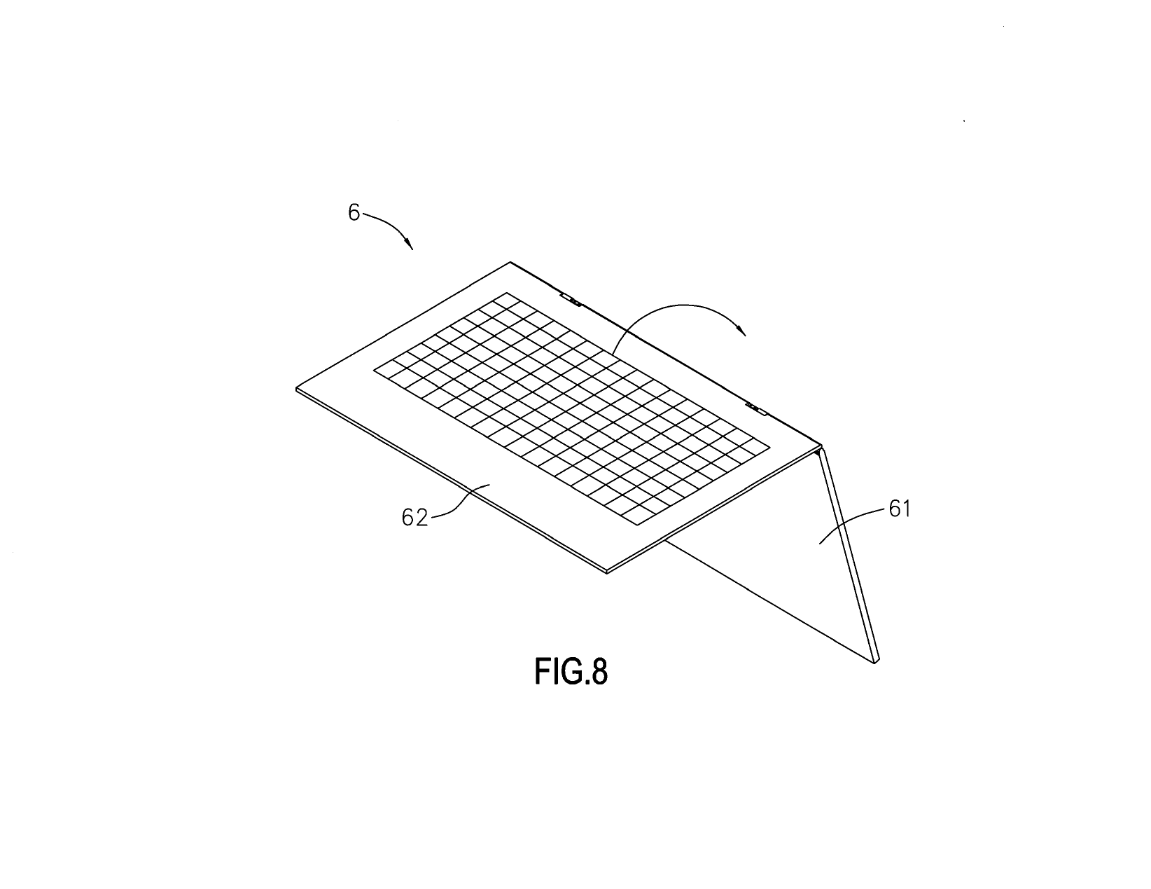

FIG. 9 illustrates the present invention of an electronic device totally turned.

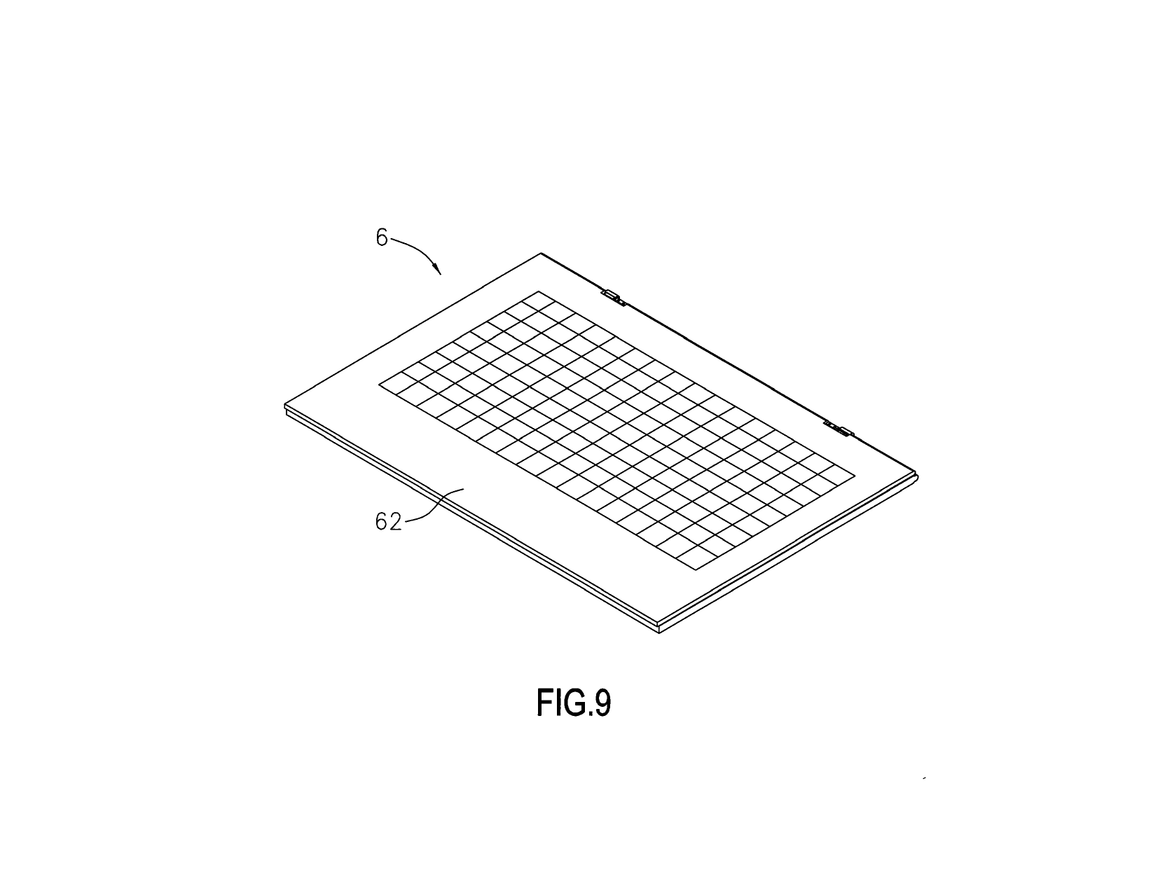

### DETAILED DESCRIPTIONS OF THE PREFERRED EMBODIMENTS

For objects, characteristics, and advantages of the present invention obviously and easily understood, the preferred embodiments along with drawings are particularly interpreted hereinafter.

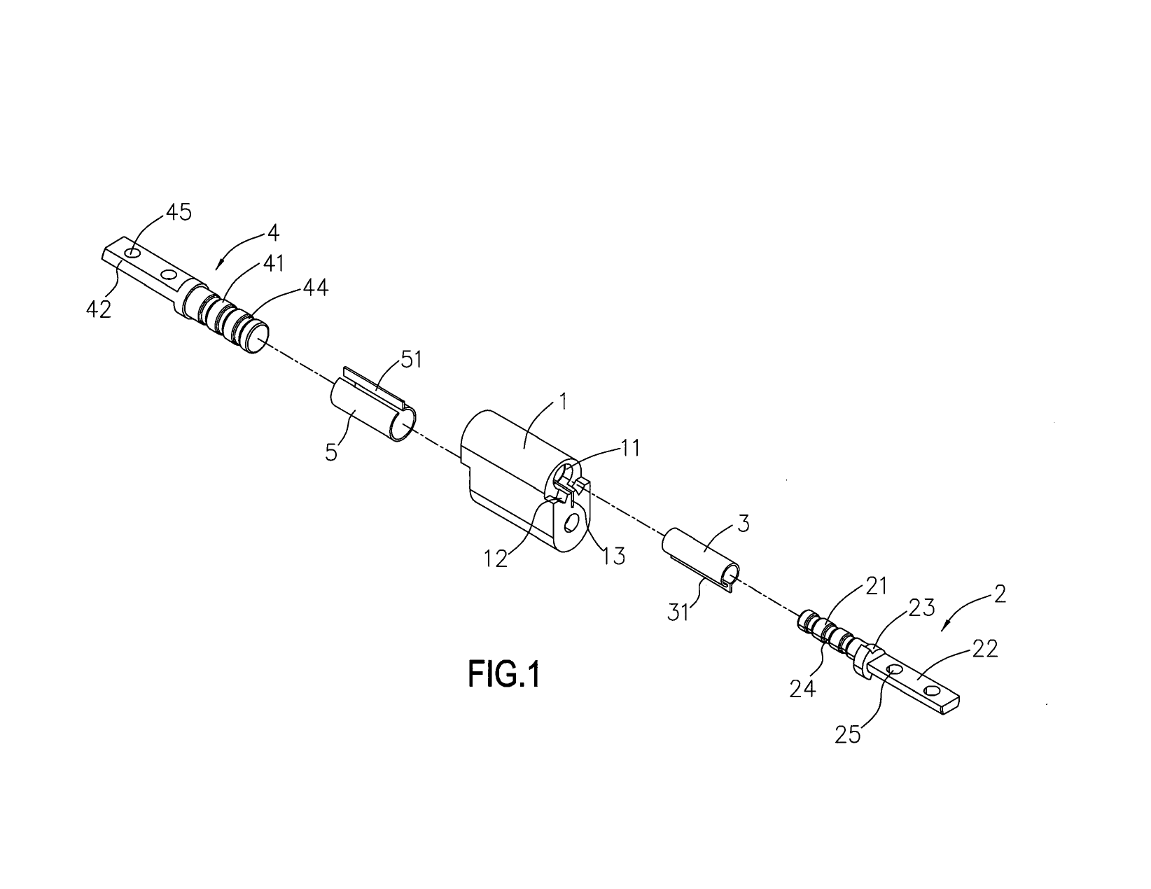

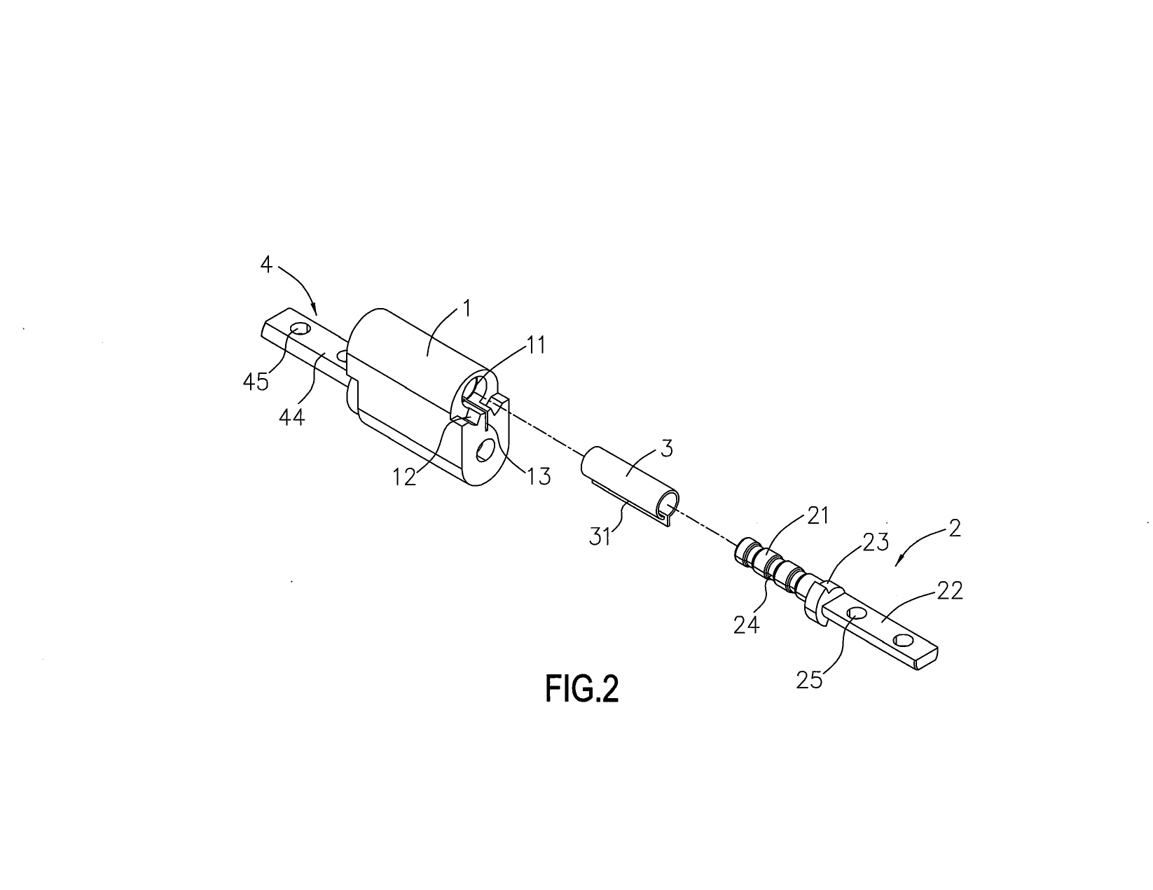

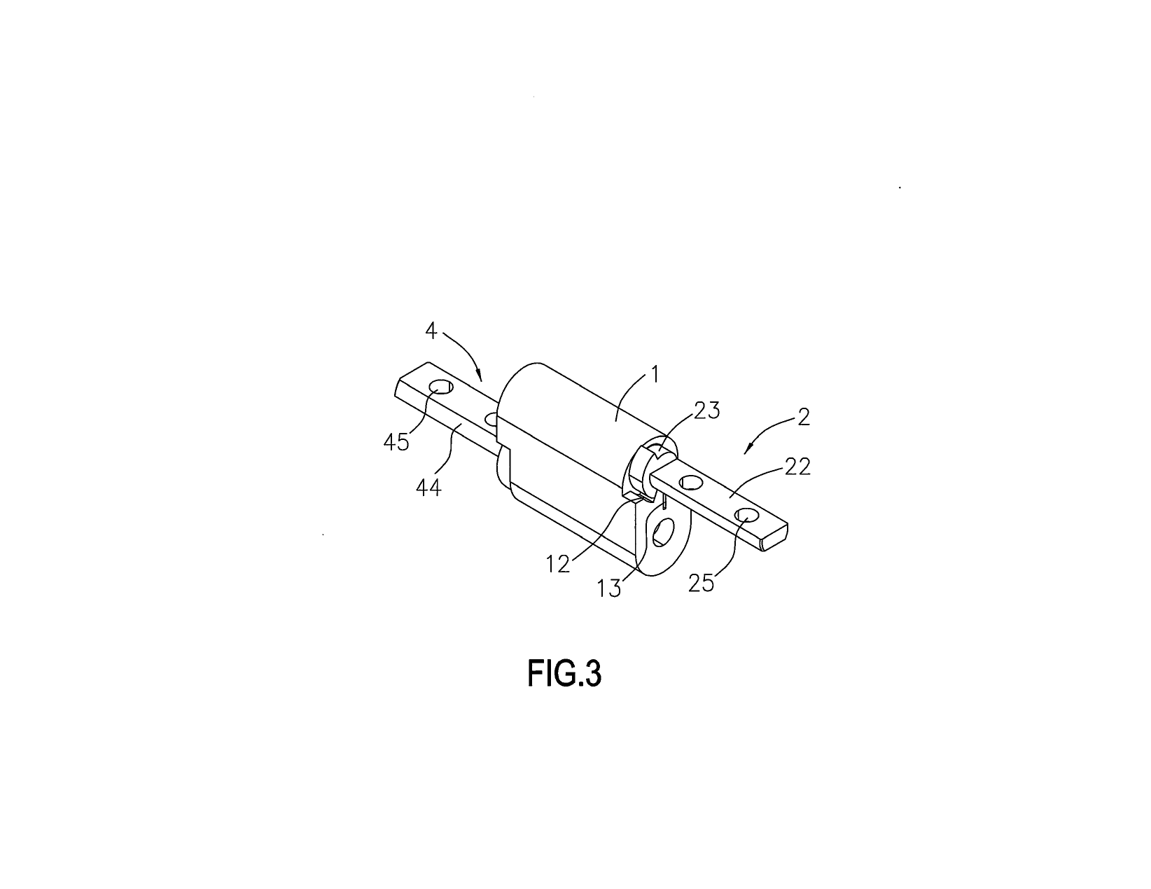

Referring to FIGS. 1, 2 and 3 which illustrate perspective views for the present invention of a twin-shaft hinge, disassembled or assembled, comprises a twin-shaft body 1, a first shaft 2, a first brake lining 3, a second shaft 4 and a second brake lining 5.

The twin-shaft body 1, a rectangle-like component, comprises mounting holes 11 at its both flanks, each of which has V-grooved retainers 12 outside its opening's both sides, and a hold-down groove 13 in the mounting hole 11 and between two V-grooved retainers 12 wherein the retainers 12 belong to but are not limited to one part of the one-piece component of the twin-shaft body 1 in this embodiment.

The first shaft 2 comprises a pivot part 21 at one end, a holder 22 linking the pivot part 21, and a stopper 23 between the pivot part 21 and the holder 22 wherein the cylindrical pivot part 21 is provided with a plurality of lubricant grooves 24 for lubricant accommodated, the holder 22 as one rectangular-sheet structure has connecting holes 25, and the stopper 23 is one chambered structure protruding outward.

The first brake lining 3 is designed to be one structure like a C-shaped sleeve on which there is a fastening slice 31 extending from an opening of the C-shaped structure and inserted into a hold-down groove 13 of the twin-shaft body 1 for the first brake lining 3 plugged into and fixed in the mounting hole 11 and wrapping the pivot part 21 of the first shaft 2 which is consequentially turned by generated friction.

The second shaft 4 comprises a pivot part 41 at one end and a holder 42 linking the pivot part 41 wherein the cylindrical pivot part 41 is provided with a plurality of lubricant grooves 44 for lubricant accommodated, the holder 42 as one rectangular-sheet structure has connecting holes 45.

The second brake lining 5 is designed to be one structure like a C-shaped sleeve on which there is a fastening slice 51 extending from an opening of the C-shaped structure and inserted into a hold-down groove 13 of the twin-shaft body 1 for the second brake lining 5 plugged into and fixed in the mounting hole 11 and wrapping the pivot part 41 of the second shaft 4 which is consequentially turned by generated friction.

The steps to assemble the present invention of a twin-shaft hinge are (a) the lubricant grooves 24 in the first shaft 2 and the lubricant grooves 44 in the second shaft 4 are filled with grease first; (b) the first brake lining 3 and the second brake lining 5 are coupled with the pivot part 21 of the first shaft 2 and the pivot part 41 of the second shaft 4 respectively for both components inserted into the mounting holes 11 of the twin-shaft body 1 simultaneously; (c) the fastening slice s 31, 51 on the brake linings 3, 5 are inserted into the hold-down grooves 13 of the twin-shaft body 1 for the brake linings 3, 5 fixed in the mounting holes 11 and used to securely hold the first shaft 2 and the second shaft 4 inside the twin-shaft body 1, respectively. In this assembled component, the stopper 23 on the first shaft 2 corresponds to one retainer 12 which coordinates the stopper 23 to restrict a turning angle of the first shaft 2 which is ready to turn; the turning shafts 2, 4 with grease lubricating between the shafts and the brake linings 3, 5 generate torsion set by one user.

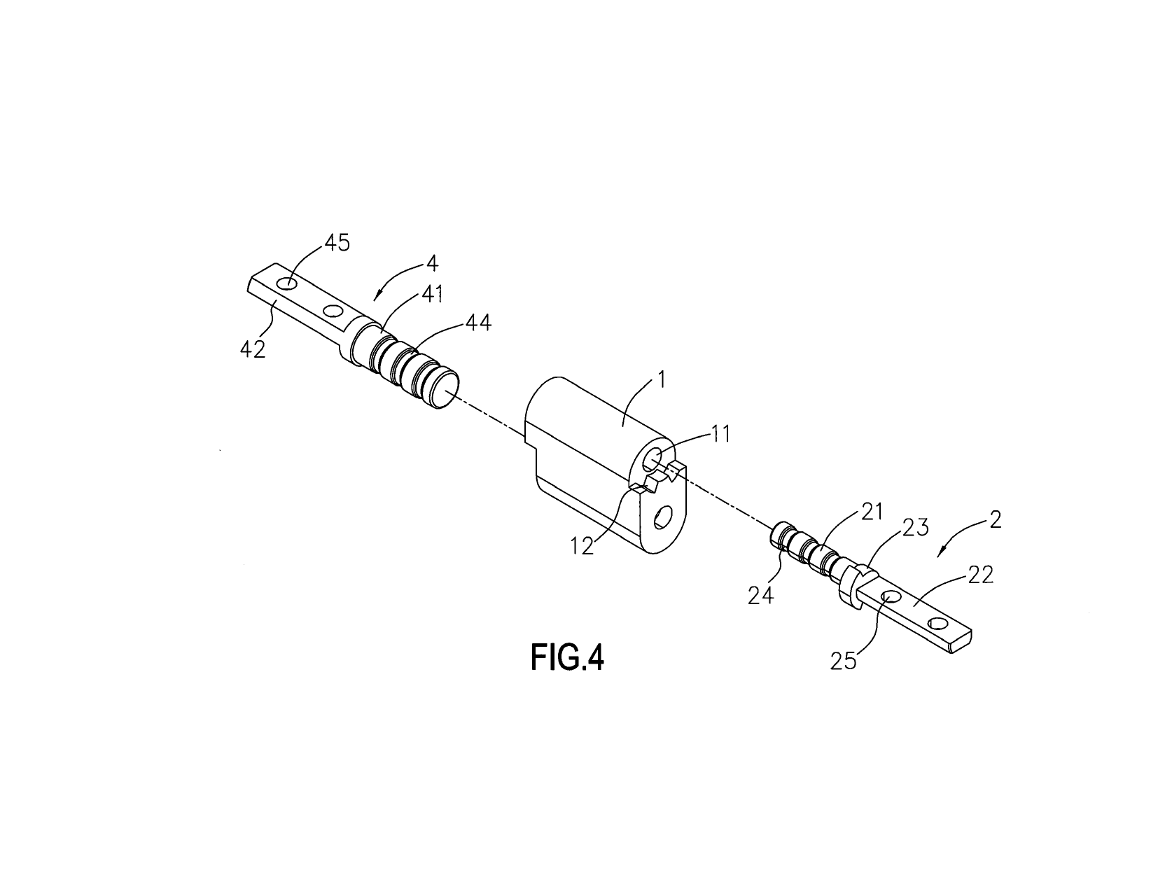

Referring to FIG. 4 which illustrates an additional embodiment for the present invention of a twin-shaft hinge. Different from the previously mentioned structure, the present invention of a twin-shaft hinge in this embodiment consists of a twin-shaft body 1, a first shaft 2 and a second shaft 4 only without brake linings 3, 5 for the shafts 2, 4 securely held in mounting holes 11 of the twin-shaft body 1 via pivot parts 21, 41, both of which rub the mounting holes 11 to reach rolling friction for the shafts 2, 4.

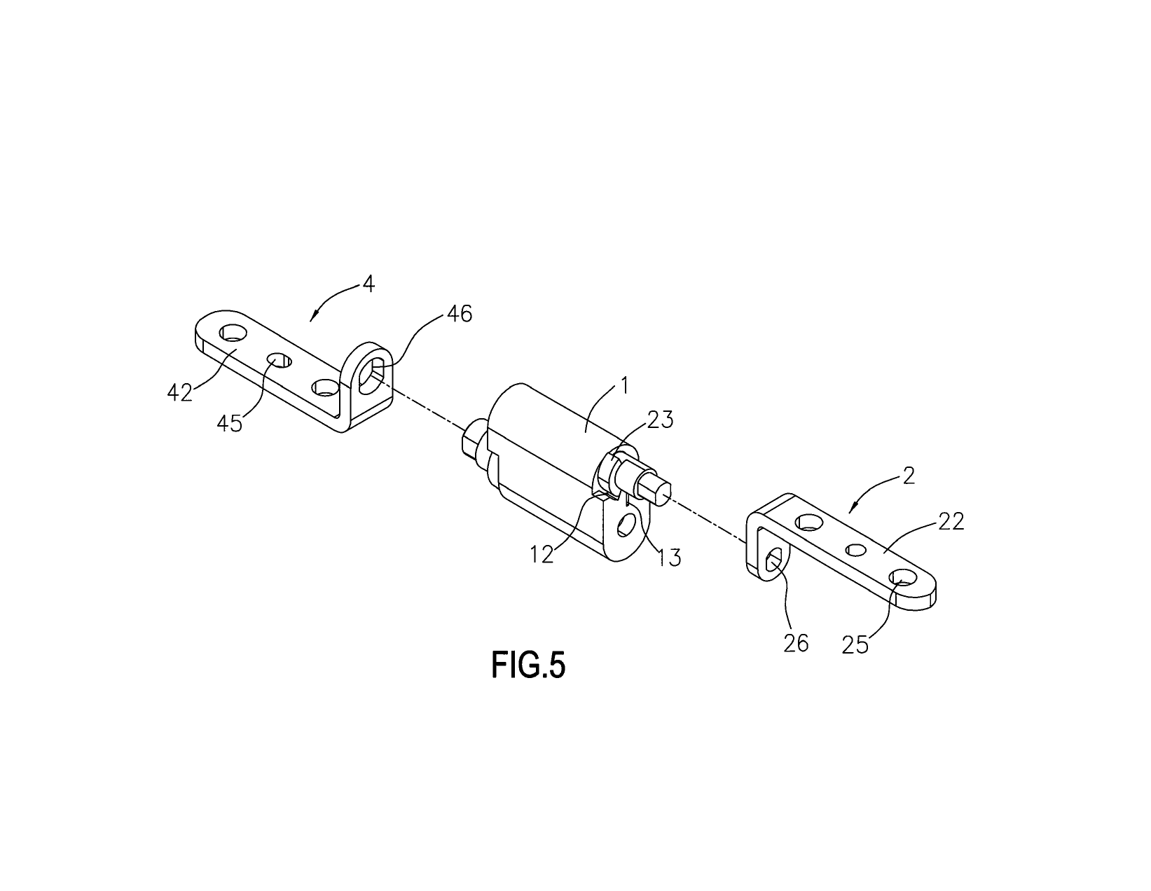

Referring to FIG. 5 which illustrates a further embodiment for the present invention of a twin-shaft hinge. As one type of separate structure, a holder 22 (or 42) individually connected to one shaft of the present invention in this embodiment has one pivot hole 26 (or 46) which is coupled with the shaft 2 (or 4) to embody both the holder 22 (or 42) and the shaft 2 (or 4) being driven simultaneously and the holder 22 (or 42) fixed on an electronic device.

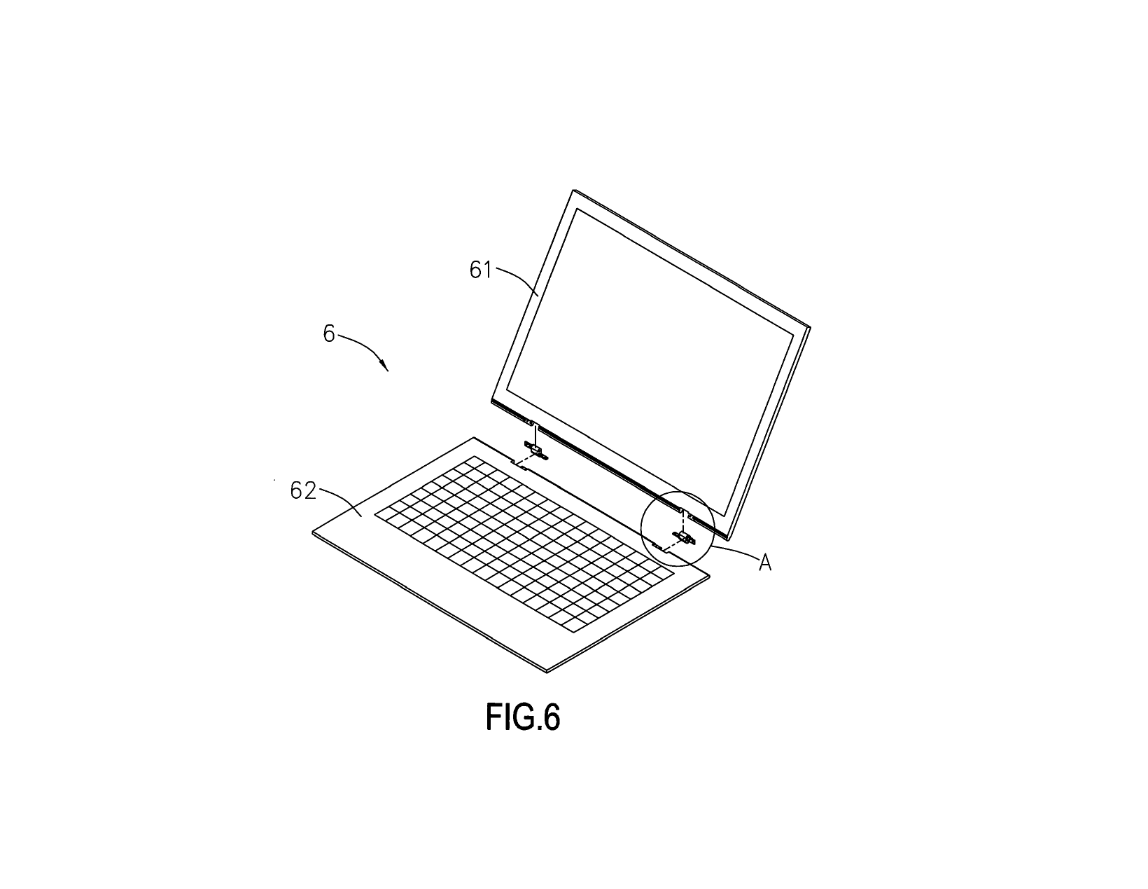

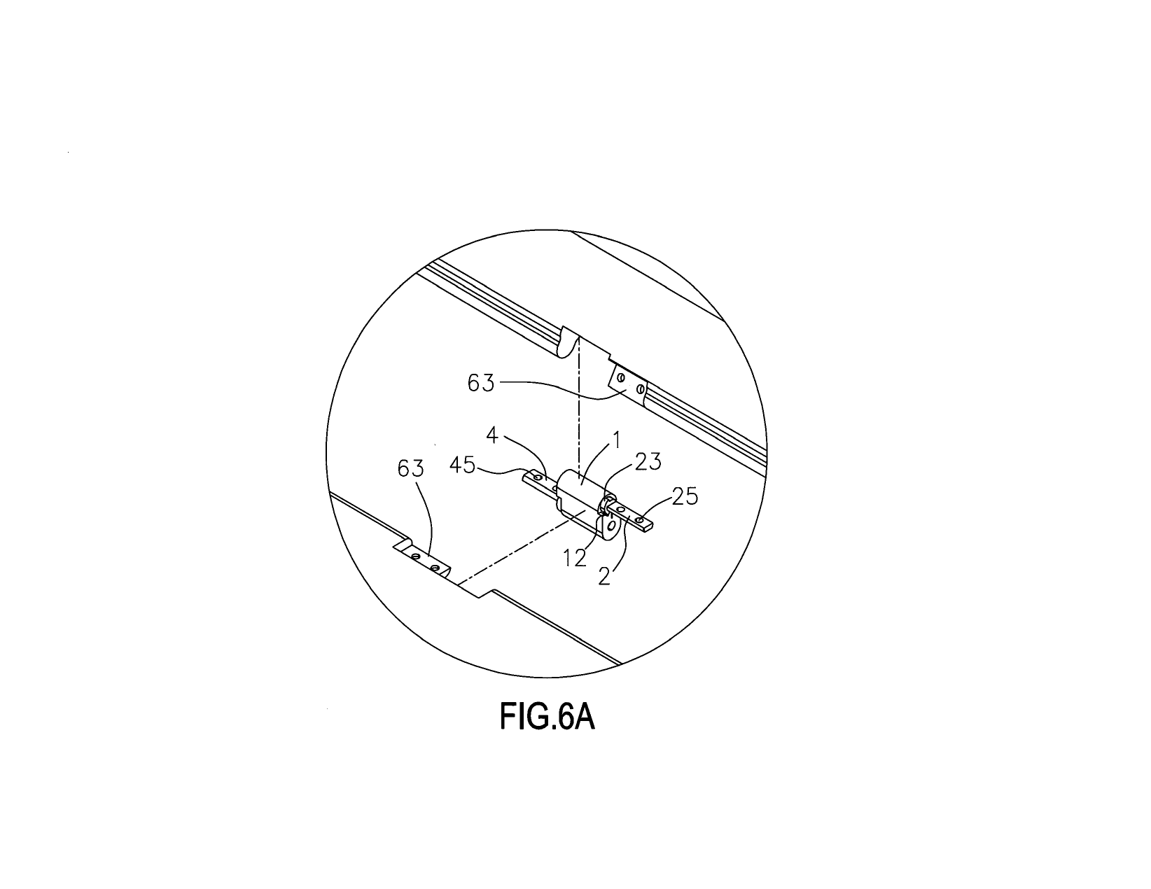

Referring to FIG. 6, 6A, 7, 8 and 9 which illustrate perspective views for the present invention of an electronic device in one embodiment wherein the present invention of an electronic device comprises a first device body 61, a second device body 62, supports 63 in the device bodies, and the twin-shaft hinge. In this embodiment, an electronic device 6 is one notebook computer and the twin-shaft hinge between a screen and a host is installed to the supports 63 of the electronic device by means of connecting holes 25, 45. The first device body 61 turned by one user is able to drive the first shaft 2 simultaneously for the first device body 61 freely opened to one angle or the maximum one with the stopper 23 and the retainer 12 on the first shaft 2 held each other. Then, the first device body 61 can be constantly turned to drive the twin-shaft body 1 via the second shaft 4 until the first device body 61 is turned to and contacts the rear side of the second device body 62 for the electronic device 6 effectively folded.

It can be seen from the said structure that the present invention provided with a twin-shaft device embodies not only a general application for one electronic device but also the turned first device body 61 over the second device body 62 for the first device body 61 overlapping the second device body 62 approximately and an electronic device's increased turning angle.

The said embodiments should be referred to as examples to explain principles and efficiency of the present invention only but do not restrict the present invention. Any person skilled in the art may make any correction or change to the embodiments without departing from technical principles and spirit of the present invention.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A twin-shaft hinge, which is used in supports of an electronic device, comprising:
a twin-shaft body on which there is at least a mounting hole with retainers designed outside;
a first shaft which has a holder at one end, a pivot part at the other end inserted into the mounting hole, and a stopper located between the pivot part and the holder and held by one retainer, and is connected to a first device body of the electronic device by means of the holder;
a second shaft which has a holder at one end and a pivot part at the other end inserted into the mounting hole and is connected to a second device body of the electronic device by means of the holder;
the first device body is turned to the maximum angle by the first shaft and further to the second device body's rear side with the second shaft in the twin-shaft body driven to turn the first device body.

2. The twin-shaft hinge according to claim 1 wherein a hold-down groove is designed between the retainers on the twin-shaft body and the pivot part on the shaft is coupled with a brake lining on which there is an extended fastening slice inserted into the hold-down groove for the brake lining fixed in a mounting hole.

3. The twin-shaft hinge according to claim 1 wherein the pivot part and the holder combine one shaft to become a one-piece structure or are separately mounted on the shaft via an assembly process.

4. The twin-shaft hinge according to claim 1 wherein the pivot part on the first shaft is provided with at least one lubricant groove for lubricant accommodated.

5. The twin-shaft hinge according to claim 1 wherein the holder on the first shaft has connecting holes used to link an electronic device.

6. The twin-shaft hinge according to claim 1 wherein the pivot part on the second shaft is provided with at least one lubricant groove for lubricant accommodated.

7. The twin-shaft hinge according to claim 1 wherein the holder on the second shaft has connecting holes used to link an electronic device.

8. An electronic device with the twin-shaft hinge, comprising:
a first device body and a support inside the first device body;
a second device body and a support inside the second device body;
the twin-shaft hinge according to claim 1 wherein the twin-shaft hinge links supports in the first device body and the second device body to turn the support corresponding to the first device body or the second device body and the first device body over the second device body's rear side.
